(19) United States
(12) Patent Application Publication
(10) Pub. No.: US 2025/0030987 A1
(43) Pub. Date: Jan. 23, 2025

(54) MICROELECTROMECHANICAL DEVICE, MICROELECTROMECHANICAL MICROPHONE AND METHOD FOR PRODUCING A MICROELECTROMECHANICAL DEVICE

(71) Applicant: Robert Bosch GmbH, Stuttgart (DE)

(72) Inventors: Jochen Reinmuth, Reutlingen (DE); Thomas Friedrich, Moessingen-Oeschingen (DE)

(21) Appl. No.: 18/772,471

(22) Filed: Jul. 15, 2024

(30) Foreign Application Priority Data
Jul. 19, 2023 (DE) 10 2023 206 864.8

(51) Int. Cl. H04R 19/04; B81B 3/00; B81C 1/00; H04R 7/04; H04R 31/00

(52) U.S. Cl. CPC H04R 19/04; B81B 3/0021; B81C 1/00158; H04R 7/04; H04R 31/003; B81B 2201/0257; B81B 2203/0127; B81B 2203/019; B81B 2203/04; B81C 2201/0109; B81C 2201/0132; H04R 2201/003; H04R 2307/023

(57) ABSTRACT

A microelectromechanical device for capacitive fluid pressure measurement. The device has a first membrane and a second membrane which can be elastically deflected by a fluid pressure, wherein a cavity is formed between the first membrane and the second membrane, in which cavity a counter electrode is arranged, wherein the counter electrode has a plurality of radial etch channels which extend radially from the center of the counter electrode to an edge of the counter electrode. A microelectromechanical microphone, and a method for producing a microelectromechanical device, are also described.

### CROSS REFERENCE

The present application claims the benefit under 35 U.S.C. § 119 of German Patent Application No. DE 10 2023 206 864.8 filed on Jul. 19, 2023, which is expressly incorporated herein in its entirety.

### FIELD

The present invention relates to a microelectromechanical device, a microelectromechanical microphone and a method for producing a microelectromechanical device.

### BACKGROUND INFORMATION

Microelectromechanical devices, also called MEMS devices, and methods for their manufacture are described in the related art.

German Patent Application No. DE 10 2014 212 340 A1 describes a MEMS microphone having a first membrane element, a counter electrode element and a low-pressure region between the first membrane element and the counter electrode element.

U.S. Pat. No. 10,362,408 B2 relates to a MEMS device having a first membrane and a second membrane, between which a cavity is formed in which a counter electrode is arranged.

German Patent Application No. DE 10 2017 204 023 A1 describes a MEMS device and a MEMS vacuum microphone. The MEMS device has a first and second membrane element and a low-pressure region formed therebetween. A counter electrode structure arranged in the low-pressure region comprises a conductive layer having a segmentation that provides electrical insulation between a first and a second portion of the conductive layer.

Korea Patent Application No. KR 10 2022 0 089 656 A describes a MEMS device having a first, second and third membrane, wherein the second membrane is arranged between the first and third membranes and comprises a plurality of openings, and wherein a negative pressure region is formed between the first and third membranes, in which a plurality of electrodes extend.

U.S. Patent Application Publication No. US 2020/0145762 A1 describes an acoustic device having a substrate, an electrically conductive first membrane and a first spacer for forming a first acoustic chamber between the first membrane and the substrate, and having an electrically conductive second membrane and a second spacer for forming a second acoustic chamber between the first and second membranes.

### SUMMARY

According to the features of the present invention, a microelectromechanical device for capacitive fluid pressure measurement is provided, wherein the device comprises a first membrane and a second membrane which can be elastically deflected by a fluid pressure, wherein a cavity is formed between the first membrane and the second membrane, in which cavity a counter electrode is arranged, and wherein the counter electrode has a plurality of radial etch channels which extend radially from a counter electrode center to a counter electrode edge.

This provides a device that is easy and reliable to manufacture. The etch channels in the counter electrode can simplify the manufacture of the device because an etchant can be better distributed in the device, thus accelerating and homogenizing the etching process. In addition, the etch channels can form through-openings in the counter electrode through which, for example, support columns can project in order to mechanically couple the first and second membranes to one another and/or to stabilize them against ambient pressure. The radial extension of the etch channels in the counter electrode ensures a high level of rigidity of the counter electrode. A plurality of etch channels can, for example, be formed by at least two etch channels.

According to an example embodiment of the present invention, the counter electrode can, for example, have a round, e.g. circular, cross section. The counter electrode may have a counter electrode edge at its circumference and a geometrically defined counter electrode center between two opposite points or portions of the counter electrode edge. An etch channel can be formed during manufacture of the device, for example, by a hollow volume in at least one material layer of the device. Alternatively or additionally, it is possible to form etch channels through structures that have an etch rate that is many times higher than a surrounding sacrificial layer material. For example, heavily doped oxide regions can advantageously be provided next to undoped oxide regions, which can be removed, for example, using a gaseous hydrogen-fluoride-based etching process.

According to an example embodiment of the present invention, the device can be designed for capacitive fluid pressure measurement. The fluid-pressure-induced deflection of the first and/or second membrane leads to a change in the distance between the deflected membrane and the substantially fixed counter electrode. Such a change in distance results in a change in the electrical capacitance between the membrane and the counter electrode compared to a base capacitance. The deflection of the first and/or second membrane can thus be converted into an electrical signal, so that the device can be referred to as an electromechanical transducer.

According to an example embodiment of the present invention, the device can be produced by applying structured material layers to a substrate. The second membrane may be arranged closer to the substrate than the first membrane, so that the first membrane can also be referred to as a membrane facing away from the substrate and the second membrane can also be referred to as a membrane facing the substrate. The first membrane may extend substantially parallel to the second membrane. The first and second membranes may extend substantially parallel to a substrate surface. A substrate recess can be formed in the substrate and can, for example, form a front and/or rear volume of the device. The second membrane can span the substrate recess. In particular, a main membrane portion of the second membrane, which will be explained below, can span the substrate recess.

According to an example embodiment of the present invention, the first membrane and the second membrane, which can be elastically deflected by a fluid pressure, can, for example, each be formed by an elastically displaceable and/or elastically deformable material layer. A membrane thickness of the first and/or the second membrane, which can be defined, for example, by a layer height of the material layer forming the membrane, can be, for example, 0.2 to 2 μm. A membrane diameter, which can correspond to the extension of the membrane perpendicular to the membrane thickness and parallel to a substrate surface, can be, for example, 400-2000 μm. An elastically deflectable membrane can be understood to be a reversibly deflectable membrane which strives to return to its starting position and/or starting shape when the acting fluid pressure decreases or is eliminated. The first and/or the second membrane can be displaceable, in particular continuously displaceable, between a starting position and a deflection position. The first membrane can be deflected by a fluid pressure acting on the first membrane. The second membrane can be deflected by a fluid pressure acting on the second membrane. The first and second membranes can be mechanically coupled, for example, by support columns extending between the membranes, in particular substantially perpendicularly between the membranes, and can be stabilized with respect to an ambient pressure of the device. By means of a mechanical coupling, the first and second membranes can also be deflected simultaneously when a fluid pressure acts on the first or second membrane. The fluid pressure can, for example, be a static, quasi-static or dynamic fluid pressure, for example it can also represent a mechanical fluid pressure oscillation, such as a sound oscillation, that causes a mechanical oscillation of the first and/or second membrane.

According to an example embodiment of the present invention, the first membrane and/or the second membrane may have a round, for example circular, cross section. The first and/or second membrane can be delimited at its circumference by a membrane edge and have a geometrically defined membrane center between two opposite points or portions of the membrane edge. The first and/or second membrane can have a membrane edge portion which can extend, for example, radially from the membrane edge towards the membrane center over a distance of at most 20% of the membrane diameter. The membrane edge portion can be a circumferential membrane edge portion. The region of the membrane extending from one membrane edge portion to an opposite membrane edge portion, in other words the membrane region adjacent to the membrane edge portion in the direction of the membrane center, can be referred to as the main membrane portion. In the main membrane portion, an acting fluid pressure can cause a larger deflection of the membrane than in the membrane edge portion. In other words, the main membrane portion is displaced and/or deformed, for example curved, to a greater extent during a deflection than in the membrane edge portion. The membrane edge portion and the main membrane portion can merge directly into one another. The terms main membrane portion and membrane edge portion may refer to a surface of the greatest extension of the first membrane. Optionally, the first membrane and/or the second membrane may have electrical insulation between the membrane edge portion and the main membrane portion to provide a structural separation between the two portions and to further concentrate a capacitance measuring range on the membrane main portion.

The cavity formed between the first and second membrane is delimited by the first membrane and the second membrane. A lateral cavity boundary extends between the first and second membranes, in particular substantially perpendicular to the first and second membranes, and can be formed, for example, by a counter electrode layer and/or further material layers of the device between the membranes. The cavity can be sealed substantially in a fluid tight manner.

According to one example embodiment of the present invention, the counter electrode can be spaced apart from a lateral cavity boundary of the cavity by a clearance channel which is circumferential at least in portions, wherein the counter electrode has at least one support arm with which it is anchored to the lateral cavity boundary and to which it can be electrically contacted. This provides a defined capacitance measuring range at the counter electrode for detecting a capacitance change caused by a deflection of the first and/or second membrane. The gap surrounding the counter electrode provided by the clearance channel allows the measurement of parasitic capacitances to be reduced or avoided, thus improving the accuracy of the detected measurement signal. In other words, the clearance channel can provide electrical insulation of the counter electrode, which leads to a more precise measurement result. In addition, the clearance channel has the advantage that it can form an etchant distribution channel during the manufacture of the device, which can contribute to the acceleration and homogenization of an etching process, for example during the etching of at least one sacrificial layer to form the cavity. The clearance channel may have a larger channel cross section than a radial etch channel of the counter electrode.

According to an example embodiment of the present invention, the counter electrode may be a substantially rigid and/or fixed structure of the device which forms a measuring capacitance with the first and/or second membrane. The counter electrode may extend substantially parallel to the first and/or second membrane. A counter electrode thickness, which can be defined, for example, by a layer height of the counter electrode or by its extension perpendicular to a substrate surface, can be, for example, 1 to 10 μm. A distance between the counter electrode and the first and/or second membrane can be, for example, 0.5 to 5 μm. The counter electrode can be coupled to the cavity boundary via at least one, in particular a plurality of support arms, wherein the support arm or the support arms can, for example, bridge or traverse the clearance channel. The counter electrode is held in the cavity by at least one support arm and can be electrically contacted via the support arm. The support arm or arms can divide the clearance channel into clearance channel segments, as will be explained in more detail later. The counter electrode can, for example, also be coupled to the cavity boundary via two, three, four or more support arms. This allows for even and stable support of the counter electrode. The support arms can, for example, be arranged in pairs diametrically opposite each other. The counter electrode can have a round, for example circular, cross section, thus forming, for example, circular counter electrode surfaces which are opposite the first membrane and the second membrane. The counter electrode may have a counter electrode edge at its circumference and a geometrically defined counter electrode center between two opposite points or portions of the counter electrode edge. The counter electrode edge can be the peripheral boundary of the counter electrode to which the clearance channel is adjacent. The cavity boundary, the clearance channel and the counter electrode can be arranged concentrically with the counter electrode center as the center.

The cavity and/or the clearance channel can be formed by a material recess in the device, for example by partially removed material layers of the device. The clearance channel can, for example, be delimited laterally by the cavity boundary and by the counter electrode and merge directly into the further cavity region between the counter electrode and the membranes. The clearance channel can extend at least in portions between a membrane edge portion of the first membrane and a membrane edge portion of the second membrane opposite the membrane edge portion of the first membrane.

According to one example embodiment of the present invention, the clearance channel can be fluidically connected to at least one etch access channel of the device, which channel extends through the first membrane. This makes it possible, during the production of the device, for the clearance channel to form an etchant distribution channel, which can contribute to the acceleration and homogenization of an etching process, for example during the etching of at least one sacrificial layer to form the cavity. A fluidic connection can be understood, for example, to mean that the clearance channel directly merges into the etch access channel or flows into it, or that the etch access channel in other words flows into the clearance channel. For example, the etch access channel may extend substantially perpendicularly through the first membrane. The first membrane may comprise a plurality of etch access channels, wherein the clearance channel may be connected to one, several or all of the etch access channels in the first membrane. An etch access channel may have a smaller channel cross section than the clearance channel.

According to one configuration of the above-described embodiment of the present invention, the etch access channel can extend through a membrane edge portion of the first membrane, wherein the membrane edge portion extends radially from a membrane edge in the direction of a membrane center of the first membrane over a distance of at most 20% of the membrane diameter. As a result, the mechanical properties of the first membrane can be maintained in the main membrane portion thereof, so that the first membrane, despite an introduced etch access channel, can be deflected evenly and does not experience any bending effects, for example due to thermal or mechanical pre-bending. The first membrane can thus be designed with a high degree of mechanical sensitivity. According to one exemplary embodiment of the present invention, it can additionally be provided that no etch access channel extends through a main membrane portion of the first membrane.

This makes it possible to avoid stiffening of the membrane, for example by closing the etch access channel in the region of the greater deflection thereof. According to further advantageous embodiments, the membrane edge portion can extend radially from a membrane edge in the direction of a membrane center of the first membrane over a distance of at most 15%, at most 10% or at most 5% of the membrane diameter, thereby further improving the mobility of the membrane. To illustrate the distance ratio for a 20% extension of the membrane edge portion, with a membrane diameter of 20 length units, for example, starting from a fixed point on the membrane edge, the membrane center can be located at 10 length units, the membrane edge portion can extend over 4 length units and, following the membrane edge portion, a main membrane portion can extend in the range of 4 to 16 length units, which in turn is followed by a 4-length-unit-long membrane edge portion of the opposite membrane edge.

According to one example embodiment of the present invention, the counter electrode can be arranged at least partially, in particular completely, between a main membrane portion of the first membrane and a main membrane portion of the second membrane opposite the main membrane portion of the first membrane. The counter electrode can, for example, be positioned between the first and second membranes in such a way that it is flush with the main membrane portions of the first and second membranes, i.e., the counter electrode surface thereof is opposite a main membrane portion. This allows the main membrane portions and the counter electrode to form defined capacitance measuring ranges. Thus, the accuracy of the capacitive fluid pressure measurement can be further improved. The main membrane portion of the first membrane can be located between two opposite membrane edge portions of the first membrane, wherein the membrane edge portions can extend, for example, radially from a membrane edge in the direction of a membrane center of the first membrane over a distance of at most 20% of the membrane diameter. The main membrane portion of the second membrane can be located between two opposite membrane edge portions of the second membrane, wherein the membrane edge portions can extend, for example, radially from a membrane edge in the direction of a membrane center of the second membrane over a distance of at most 20% of the membrane diameter.

According to one example embodiment of the present invention, the clearance channel can be divided into several clearance channel segments and each clearance channel segment can be fluidically connected to at least one etch access channel. This can simplify the manufacture of the device, since an etchant can be distributed more evenly and via a plurality of access points in the device at the same time, so that an acceleration and homogenization of the etching process is achieved. The clearance channel can be segmented, for example by the support arms of the counter electrode. For example, the clearance channel can be divided into four clearance channel segments by four support arms, whereby each clearance channel segment can be connected to an etch access channel.

According to one example embodiment of the present invention, a gas volume that has a gas pressure below ambient air pressure can be enclosed in the cavity. In this way, thermal noise and squeeze-film damping effects are effectively eliminated in the capacitive fluid pressure measurement. The gas volume can be enclosed during manufacture of the device, for example, in a simple and reliable manner via at least one etch access channel of the device and the closure thereof. The etch access channel can advantageously extend through a membrane edge portion of the first membrane, so that the etch access channel and closure thereof do not affect or hardly affect the main membrane portion, for example through local stiffening or bending effects.

According to one example embodiment of the above-described embodiment of the present invention, the gas volume can be enclosed by a closure of the at least one etch access channel. The closure may, for example, comprise a dielectric layer and/or a metallic layer. If the closure has a dielectric layer and a metallic layer, the metallic layer can, for example, be applied to the dielectric layer. The metallic layer can, for example, contain aluminum. The dielectric layer can be formed, for example, from silicon dioxide or silicon nitride. The dielectric layer can be designed for gas-tight enclosure of the gas volume. The metallic layer can provide a long service life and reliable sealing of the closure. In principle, a closure can also be achieved by locally melting the membrane material.

According to one example embodiment of the present invention, the first membrane, the second membrane and/or the counter electrode may be made of polysilicon. This allows very advantageous mechanical properties of the membranes and/or the counter electrode to be achieved while at the same time maintaining favorable electrical conductivity. In addition, polysilicon can be easily structured. The polysilicon can, for example, be doped polysilicon. The first membrane and/or the second membrane as well as the counter electrode can be formed by a polysilicon layer, wherein the polysilicon layer of the membrane has a smaller layer thickness than the polysilicon layer of the counter electrode. The counter electrode can, for example, also be made of a plurality of polysilicon layers applied on top of each other. This makes it possible to form an elastically deflectable membrane and a substantially rigid, fixed counter electrode using the same material.

The present invention also relates to a microelectromechanical microphone for capacitive sound pressure measurement, which has a microelectromechanical device according to one of the features described above and a signal processing unit for applying and processing signals from the microelectromechanical device. This makes it possible to provide a compact and powerful microphone with a sensitive, precise and particle-insensitive sound pressure measurement, a very good signal-to-noise ratio, and reduced fluidic squeeze-film damping effects. The microphone can be a capacitive microphone, i.e., an electroacoustic transducer that converts sound into a corresponding electrical signal by detecting capacitance changes caused by changes in the distance between the first electrode and/or the second membrane and the counter electrode. The microelectromechanical microphone can, for example, be implemented as a system-on-chip (SoC).

The present invention also relates to a method for producing a microelectromechanical device for capacitive fluid pressure measurement having a first membrane and a second membrane which can be elastically deflected by a fluid pressure, wherein a cavity is formed between the first membrane and the second membrane, in which cavity a counter electrode is arranged, wherein the device is produced by gradually applying and structuring material layers on a substrate and wherein the cavity is formed by applying and subsequently etching at least one sacrificial layer, wherein during manufacture a counter electrode layer is applied to form a counter electrode and the counter electrode layer and/or the sacrificial layer is structured in such a way that a plurality of radial etch channels is produced in the counter electrode and/or in the sacrificial layer, wherein the radial etch channels in the counter electrode extend radially from a counter electrode center to a counter electrode edge and/or in the sacrificial layer. In particular, the radial etch channels in the sacrificial layer can extend radially, parallel to an extension of the counter electrode, from a counter electrode center to a counter electrode edge. In particular, the radial etch channels may extend in a sacrificial layer that extends adjacent to the counter electrode layer, for example directly below or directly above the counter electrode layer.

The design of the radial etch channels in the counter electrode and/or in the at least one sacrificial layer can simplify the manufacture of the device and an etching process can be efficiently controlled because an etchant can be better distributed in the device, thus accelerating and homogenizing the etching process. To create the etch channels, narrow trenches can be etched into the counter electrode layer or into the sacrificial layer and are then closed with a second sacrificial layer. Capillary effects can create trench cavities in the narrow trenches, which can be used as etch channels. Depending on the embodiment, additional vertical etch channels can be created, wherein vertical etch channels can extend substantially perpendicularly to a main extension of the counter electrode layer.

According to one example embodiment of the present invention, an optional special layer can be applied and optionally structured between a first membrane layer, which can later form a second membrane of the device, and the substrate. The optional special layer can, for example, form a dielectric insulation layer or an etch stop layer. The optional special layer can, for example, be a silicon nitride layer. An etch stop layer allows, for example, a subsequent etching process for creating a substrate recess in the substrate to be better controlled. Optional structuring allows the special layer to be prepared, for example, for the production of an electrical connection.

The first membrane layer can be applied to the special layer or directly to the substrate. The first membrane layer can, for example, be a doped polysilicon layer. According to one embodiment, the layer thickness of the first membrane layer can be at most 2 μm.

A first sacrificial layer can be applied to the first membrane layer and optionally structured. Optional structuring allows the first sacrificial layer to be prepared, for example, for the production of an electrical connection. The first sacrificial layer can, for example, be a silicon oxide layer.

A counter electrode layer can be applied to the first sacrificial layer. The counter electrode layer can, for example, subsequently form a counter electrode, lateral cavity boundaries and support arms of the device. The counter electrode layer can be produced in a single layer or in multiple layers, for example by applying a plurality of polysilicon layers. According to one embodiment, the counter electrode layer can be deposited such that it is under tensile stress. This allows a higher level of rigidity of the counter electrode to be achieved compared to the first and second membrane and the counter electrode can have a very thin design. In addition, buckling effects can be reliably prevented, since layers under compressive stress can tend to deflect spontaneously and tensile stress can counteract this behavior.

According to one example embodiment of the method of the present invention, the structuring of the counter electrode layer is carried out in such a way that the counter electrode is spaced apart from a lateral cavity boundary of the cavity by a clearance channel which is circumferential at least in portions and is anchored to the lateral cavity boundary with at least one support arm. This makes it possible to produce a device with a defined capacitance measuring range of the counter electrode, which enables a high level of measurement accuracy in the capacitive fluid pressure measurement using the device. In addition, the clearance channel created during manufacturing facilitates the distribution of an etchant in the device, for example to create a cavity in the device, so that the manufacture of the device is simplified and an etching process of the manufacturing process can be efficiently controlled.

Part of the counter electrode layer can be removed to create the clearance channel. For this purpose, for example, through-openings can be etched into the second sacrificial layer in order to subsequently remove the material of the counter electrode layer below the through-openings, for example by means of an isotropic etching process. The through-openings can be closed by depositing a third sacrificial layer. The second sacrificial layer and/or the third sacrificial layer may be a silicon oxide layer. The second sacrificial layer and the third sacrificial layer may have a common layer thickness that substantially corresponds to the layer thickness of the first sacrificial layer. This ensures that subsequently the height of the cavity region between the first membrane and the counter electrode is substantially equal to that of a cavity region between the second membrane and the counter electrode.

A second membrane layer can be applied and structured on the third sacrificial layer, which can later form the first membrane of the device. The second membrane layer can be a doped polysilicon layer. According to one embodiment, the layer thickness of the second membrane layer can be at most 2 μm.

According to one example embodiment of the present invention, a first membrane layer can be applied to produce the second membrane and a second membrane layer can be applied to produce the first membrane and structured such that at least one etch access channel is produced in an edge portion of the first membrane. This makes it possible for the etch access channel and the closure thereof to have little or no impact on the main membrane portion of the first membrane later during operation of the device. For example, narrow trenches can be created in the second membrane layer as access points, which can form etch access channels. The access points can be created in particular in regions of the second membrane layer, which subsequently form membrane edge portions of the first membrane. Optionally, electrical insulation can be introduced into the second membrane layer in order to structurally separate a subsequent main membrane portion from an adjacent membrane edge portion and to concentrate a capacitance measuring range on the main membrane portion.

Following the formation of the etch access channels, a sacrificial layer etch may be performed to remove the first sacrificial layer, the second sacrificial layer, and the third sacrificial layer, thereby creating a cavity in the device. The sacrificial layer etch can be carried out, for example, using a hydrogen-fluoride-based etching process. Subsequently, a negative pressure can be created in the cavity and the cavity can be sealed so as to be fluid tight, for example by plasma deposition with deposition of a dielectric layer. A metallic layer can then be deposited and structured to ensure a particularly robust and tight closure of the etch access channels over a long period of time. In addition, the metallic layer can be used as a contact layer. The dielectric layer and the metallic layer can be removed in all regions above the second membrane layer except for the closures, at least in the region of a subsequent main membrane portion of the first membrane.

Subsequently, a substrate recess can be created, for example to form a front and/or rear volume of the device. This can be done, for example, by rear-side etching, wherein the rear-side etching can advantageously stop on the optional special layer if this is designed as an etch stop layer. In this case, the special layer can then be removed after the rear-side etching to ensure optimum mobility of the second membrane, at least in the main membrane portion thereof.

In general, in the context of this application, the words “a/an,” unless expressly defined otherwise, are not to be understood as numerals, but as indefinite articles with the literal meaning of “at least one.”

The present invention allows for various embodiments and is explained in more detail below using an exemplary embodiment with the figures.

### BRIEF DESCRIPTION OF THE DRAWINGS

FIGS. 1A-1D show a microelectromechanical device according to an example embodiment of the present invention in a cross-sectional plan view and lateral cross-sectional views.

FIGS. 2A-2G show a method for manufacturing the microelectromechanical device according to an example embodiment of the present invention using lateral cross-sectional views along the intersection I-I shown in FIG. 1A.

FIGS. 3A-3G show the method for manufacturing the microelectromechanical device according to an example embodiment of the present invention using lateral cross-sectional views along the intersection II-II shown in FIG. 1A.

FIGS. 4A-4B are schematic diagrams for the production of radial etch channels in a sacrificial layer, according to an example embodiment of the present invention.

FIG. 5 is a schematic diagram of a microelectromechanical microphone having a microelectromechanical device, according to an example embodiment of the present invention.

### DETAILED DESCRIPTION OF EXAMPLE EMBODIMENTS

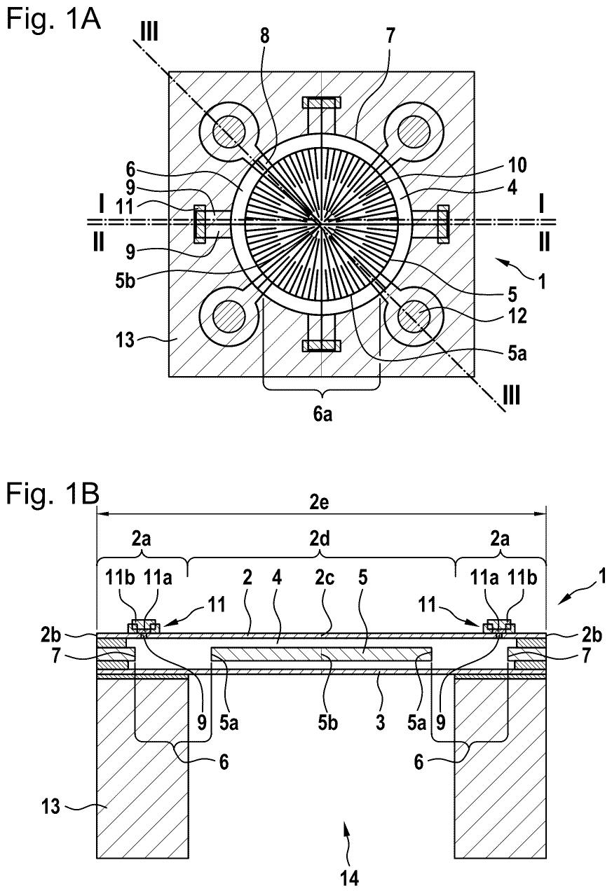

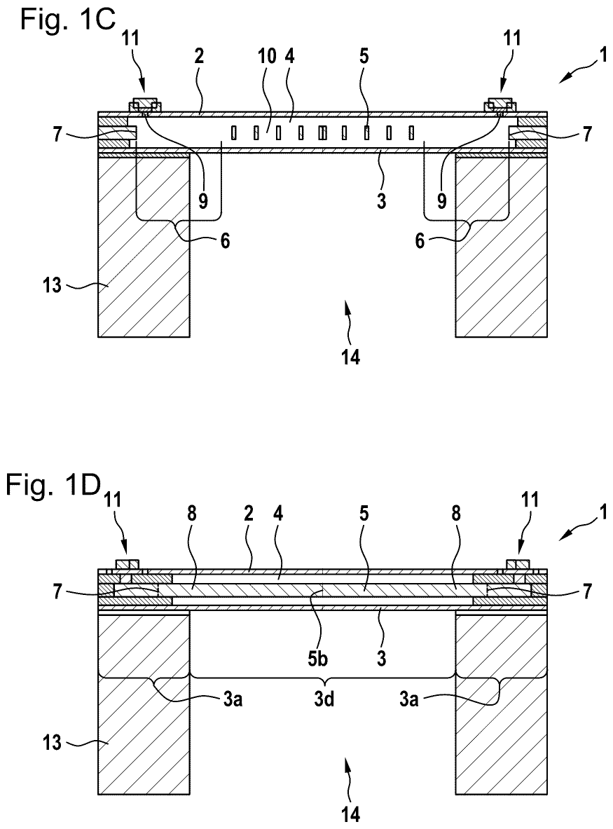

FIGS. 1A, 1B, 1C and 1D show a microelectromechanical device 1 according to an embodiment, wherein FIG. 1A shows a cross-sectional plan view, FIG. 1B shows a lateral cross-sectional view along the intersection I-I shown in FIG. 1A, FIG. 1C shows a lateral cross-sectional view along the intersection II-II shown in FIG. 1A and FIG. 1D shows a lateral cross-sectional view of the device 1 along the intersection III-III shown in FIG. 1A.

The device 1 is designed for capacitive fluid pressure measurement. As can be seen in FIGS. 1B, 1C and 1D, the device 1 comprises a first membrane 2 and a second membrane 3 which can be elastically deflected by a fluid pressure. The fluid pressure can, for example, be a static, quasi-static or dynamic fluid pressure, in particular also a sound pressure. The second membrane 3 extends substantially parallel to the first membrane 2. The device 1 is produced by applying structured material layers to a substrate 13. The second membrane 3 is arranged closer to the substrate 13 than the first membrane 2. A substrate recess 14 is introduced into the substrate 13 and can form a front and/or rear volume of the device 1. The second membrane 3 spans the substrate recess 14. The first membrane 2 and the second membrane 3 have a circular cross section. As shown in FIG. 1B, the first membrane 2 is delimited at its circumference by a membrane edge 2b. The first membrane 2 has a geometric membrane center 2c. The first membrane 2 has a circumferential membrane edge portion 2a which extends radially from the membrane edge 2b in the direction of the membrane center 2c, but occupies a distance of at most 20% of the membrane diameter 2e from any point on the membrane edge 2b. Adjacent to the membrane edge portion 2a, the first membrane 2 has a main membrane portion 2d, in the region of which a greater deflection of the first membrane 2 occurs than in the membrane edge portion 2a when a fluid pressure acts on the first membrane 2. The membrane edge portion 2a and the main membrane portion 2d merge directly into one another as shown.

Although not provided with reference numbers in FIGS. 1A to 1D for reasons of clarity, the second membrane 3 also comprises a membrane edge, a membrane center and a membrane diameter. In addition, the second membrane 3 has a membrane edge portion 3a and a main membrane portion 3d, as shown in FIG. 1D.

A cavity 4 is formed between the first membrane 2 and the second membrane 3 and is delimited by them. A lateral cavity boundary 7 extends circumferentially between the first membrane 2 and the second membrane 3. The cavity 4 can be sealed so as to be substantially fluid tight.

A counter electrode 5, shown in cross-sectional view in FIG. 1A, is arranged in the cavity 4. As shown, the counter electrode 5 has a circular cross section having a counter electrode edge 5a and a counter electrode center 5b. The further design of the counter electrode 5 can be additionally understood from FIG. 1B, 1c and 1d according to intersections I, II and III shown in FIG. 1A. The counter electrode 5 can form a substantially rigid and/or fixed structure of the device 1, which forms a measuring capacitance with the first membrane 2 and/or with the second membrane 3. The counter electrode 5 is spaced apart from a lateral cavity boundary 7 of the cavity 4 by a clearance channel 6 which is circumferential at least in portions. According to the embodiment shown, the counter electrode 5 comprises four support arms 8 with which it is anchored to the lateral cavity boundary 7 and can be electrically contacted by connection contacts 12. The support arms 8 are arranged in pairs diametrically opposite each other. In FIG. 1D it is shown that a support arm 8 can be formed by a counter electrode layer G of the device. In other words, the counter electrode 5 can be extended in the region of the support arm 8 up to the lateral cavity boundary 7 and merge there into it. By means of the clearance channel 6, which forms a gap and thus an electrical insulation of the counter electrode 5, parasitic capacitances can be reduced and a defined capacitance measuring range can be provided for detecting capacitance changes between the membranes 2, 3 and the counter electrode 5. In addition, the clearance channel 6 can form an etchant distribution channel, which can serve for improved distribution of etchants in the device 1, as will be explained in more detail later in connection with a presented manufacturing method of the device 1. The lateral cavity boundary 7, the clearance channel 6 and the counter electrode 5 are arranged concentrically to the counter electrode center 5b as the center, as shown in FIG. 1A. As can be seen in FIG. 1B, the clearance channel 6 is laterally limited by the cavity boundary 7 and the counter electrode 5 and merges directly into the further cavity region between the counter electrode 5 and the membranes 2, 3. The clearance channel 6 extends at least in portions between a membrane edge portion 2a of the first membrane 2 and a membrane edge portion of the second membrane 3 opposite the membrane edge portion 2a of the first membrane 2. According to the exemplary embodiment shown, the counter electrode 5 is arranged completely between the main membrane portion 2d of the first membrane 2 and the main membrane portion 3d of the second membrane 3, so that a very precise measurement signal can be provided.

As can be seen in FIGS. 1A and 1C, the counter electrode 5 has a plurality of etch channels 10 which extend radially from a counter electrode center 5b to a counter electrode edge 5a and open into the clearance channel 6. This can simplify the manufacture of the device 1, since an etchant can be better distributed in the device 1 through the etch channels 10.

For reasons of clarity, support columns which extend substantially perpendicularly between the membranes 2, 3 and mechanically couple them and stabilize them against an ambient pressure of the device 1 are not shown further. The support columns can, for example, extend through the etch channels 10 shown in FIG. 1C and explained later.

In the membrane edge portions 2a of the first membrane 2, etch access channels 9, which open into the clearance channel 6, extend as shown in FIGS. 1A, 1B and 1C. As a result, the clearance channel 6 can be used as an etchant distribution channel during manufacture of the device 1. Because the etch access channels 9 are arranged in the membrane edge portions 2a of the first membrane 2, the mechanical properties of the first membrane 2 in the main membrane portion 2d thereof can be maintained and bending effects can be avoided.

In FIG. 1A it can be seen that the clearance channel 6 is divided by the support arms 8 into a plurality of, here four, clearance channel segments 6a. Each clearance channel segment 6a is fluidically connected to an etch access channel 9. The clearance channel segments 6a can be supplied with an etchant evenly and rapidly via the etch access channels 9.

According to the embodiment shown, a gas volume having a gas pressure below ambient air pressure is enclosed in the cavity 4 in order to reduce thermal noise and squeeze-film damping effects. The generation of negative pressure in the cavity 4 is made possible during the manufacture of the device 1 via the etch access channel 9, which is sealed so as to be fluid tight by a closure 11 during operation of the device 1. The closure 11 has a dielectric layer 11a and a metallic layer 11b applied thereon.

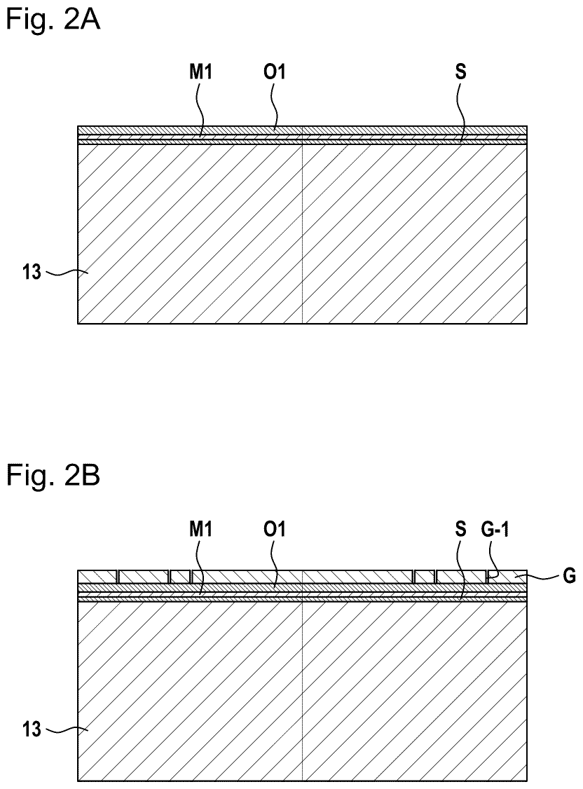

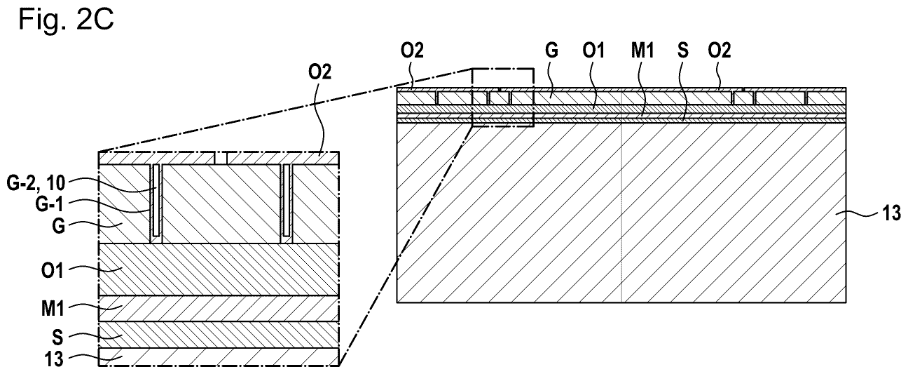

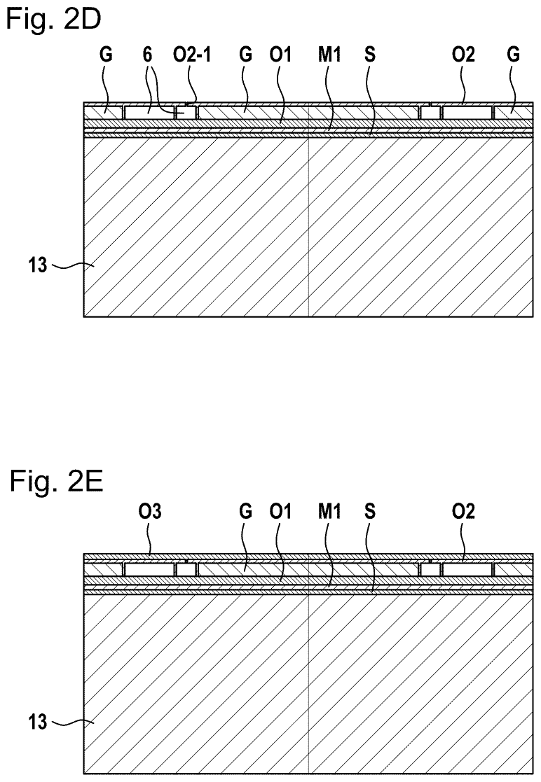

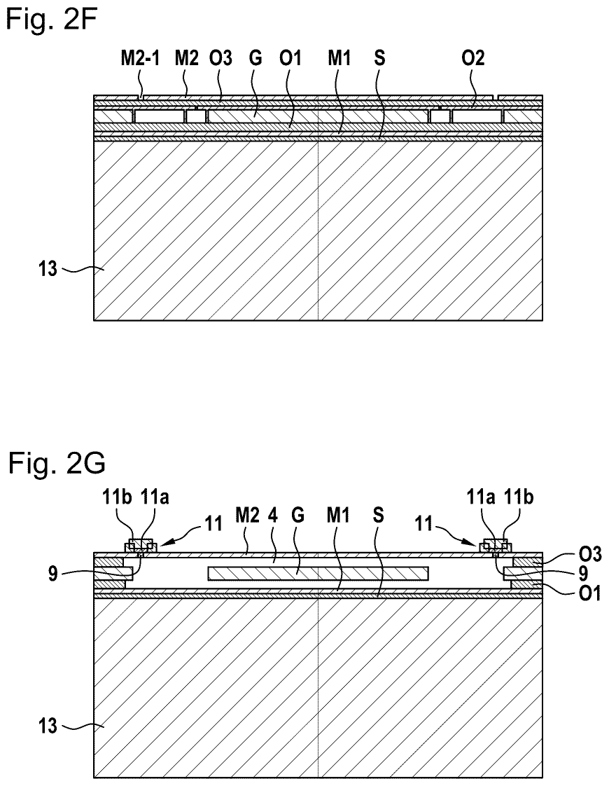

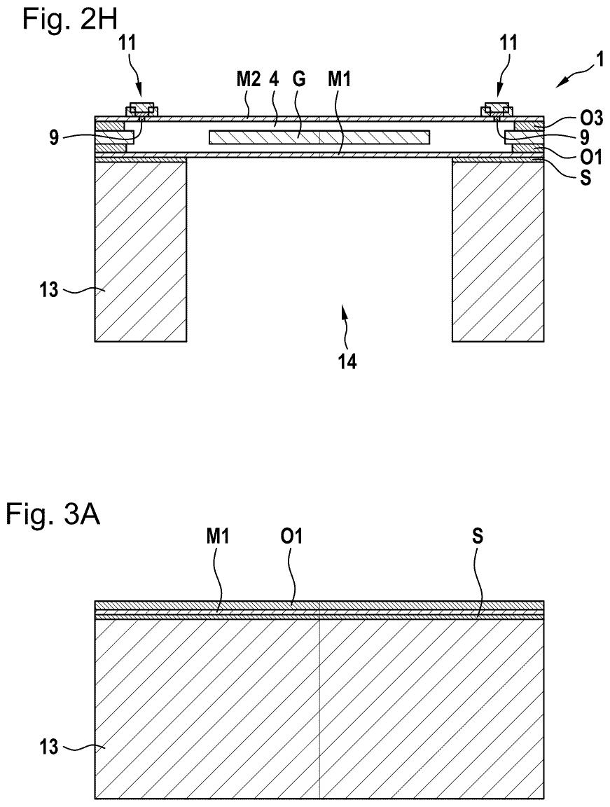

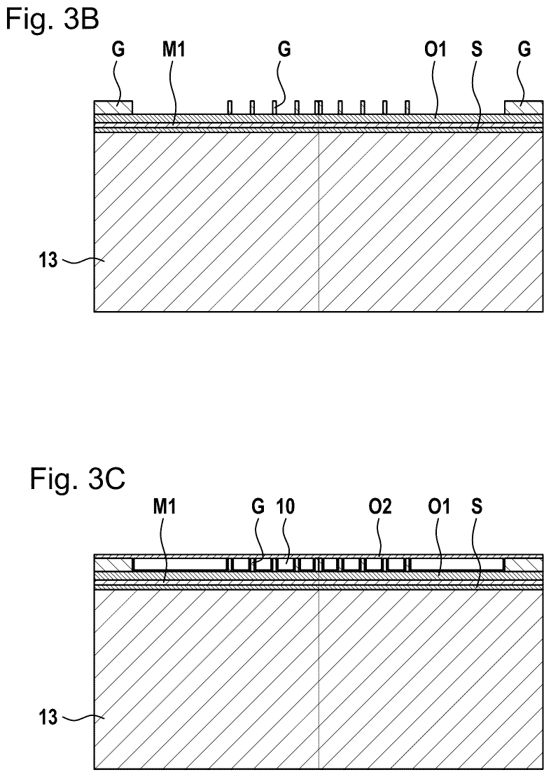

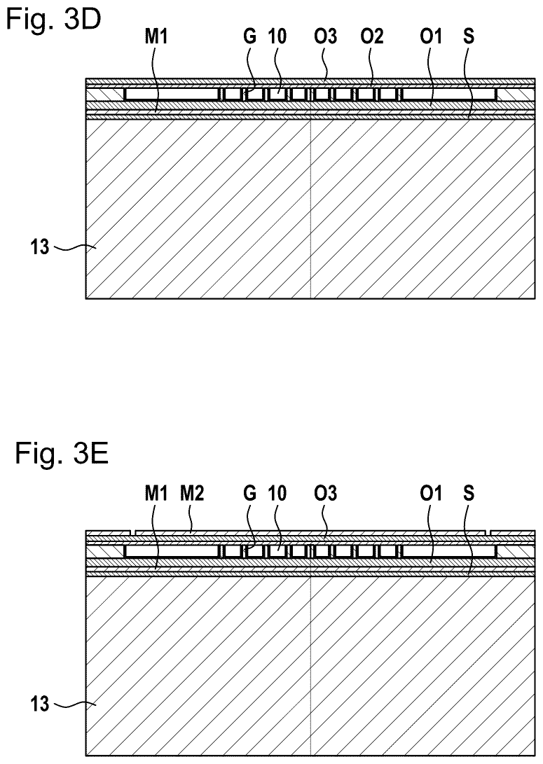

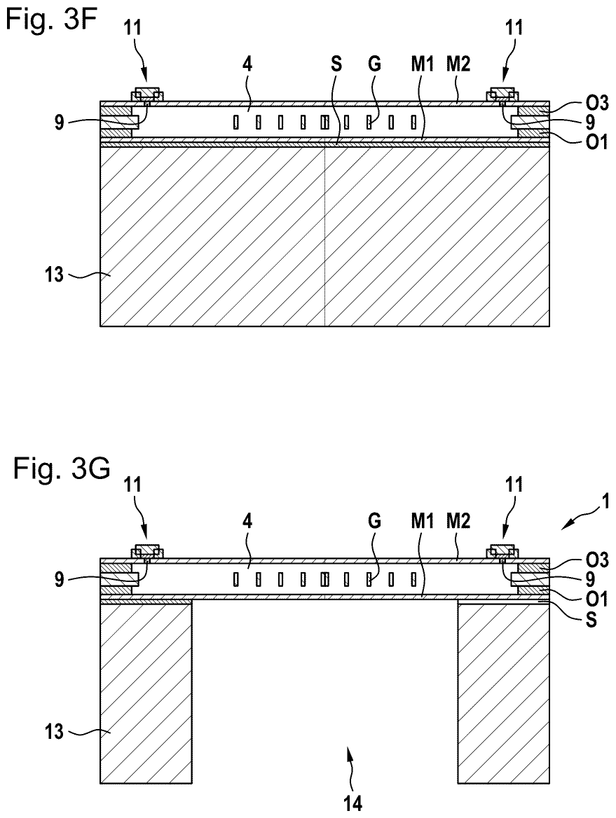

A method for producing the device 1 is explained below with reference to FIGS. 2A to 2H and 3A-3G.

According to the illustration in FIGS. 2A and 3A, an optional special layer S can first be applied to a substrate 13 and optionally structured. The optional special layer S can, for example, form a dielectric insulation layer or an etch stop layer. An etch stop layer allows, for example, a subsequent etching process for creating a substrate recess 14 in the substrate 13 to be better controlled. Optional structuring allows the special layer S to be prepared, for example, for production of an electrical connection. Following the optional application and optional structuring of the special layer S, a first membrane layer M1 is applied to the special layer S. Alternatively, the first membrane layer M1 can also be applied directly to the substrate 13. The first membrane layer M1 can, for example, be a doped polysilicon layer. According to one embodiment, the layer thickness of the first membrane layer M1 can be at most 2 μm. The first membrane layer M1 can subsequently form a second membrane 3 of the device 1. A first sacrificial layer O1 can be applied to the first membrane layer M1 and optionally structured. By means of optional structuring, the first sacrificial layer O1 can be prepared, for example, for the production of an electrical connection. The first sacrificial layer O1 can, for example, be a silicon oxide layer. The first sacrificial layer O1 can subsequently form a cavity portion of the device 1.

As shown in FIGS. 2B and 3B, a counter electrode layer G can be applied to the first sacrificial layer O1. According to the exemplary embodiment shown, the counter electrode layer G can subsequently form a counter electrode 5, lateral cavity boundaries 7 and support arms 8 of the device 1. The counter electrode layer G can be produced in a single layer or in multiple layers, for example by applying a plurality of polysilicon layers. According to one embodiment, the counter electrode layer G can be deposited such that it is under tensile stress. In preparation for the production of etch channels 10, narrow trenches G1 are etched into the counter electrode layer G.

As shown in FIGS. 2C and 3C, the narrow trenches G1 are closed with a second sacrificial layer O2. Capillary effects in the narrow trenches G1 create trench cavities G2, which can be used as etch channels 10. Depending on the embodiment, additional vertical etch channels 10 can be created. An etch channel 10 can, for example, be formed by a hollow volume in at least one material layer of the device 1. Alternatively or additionally, it is possible to form etch channels 10 by structures that have an etch rate that is many times higher than a surrounding sacrificial layer material. For example, heavily doped oxide regions can advantageously be provided next to undoped oxide regions, which can be removed, for example, using a gaseous hydrogen-fluoride-based etching process.

As shown in FIG. 2D, a part of the counter electrode layer G is removed in order to form a subsequent clearance channel 6 of the device 1. For this purpose, for example, through-openings O2-1 can be etched into the second sacrificial layer O2 in order to subsequently remove the material of the counter electrode layer G below the through-openings O2-1, for example by means of an isotropic etching process.

As shown in FIG. 2E and FIG. 3D, the through-openings O2-1 can be closed by deposition of a third sacrificial layer O3. Optionally, the second sacrificial layer O2 and/or the third sacrificial layer O3 can be structured. The second sacrificial layer O2 and/or the third sacrificial layer O3 may be a silicon oxide layer. The second sacrificial layer O2 and the third sacrificial layer O3 may have a common layer thickness that substantially corresponds to the layer thickness of the first sacrificial layer O1. This ensures that subsequently the height of the cavity region between the first membrane 2 and the counter electrode 5 is substantially identical to that of a cavity region between the second membrane 3 and the counter electrode 5.

According to the illustration in FIGS. 2F and 3E, a second membrane layer M2 is applied and structured on the third sacrificial layer O3, which can later form a first membrane 2 of the device 1. The second membrane layer M2 can in particular be a doped polysilicon layer. According to one embodiment, the layer thickness of the second membrane layer M2 can be at most 2 μm. In the second membrane layer M2, narrow trenches are created as access points M2-1, which can form etch access channels 9. The access points M2-1 are created in regions of the second membrane layer M2, which will subsequently form membrane edge portions 2a of the first membrane 2. Optionally, an electrical insulation can be introduced into the second membrane layer M2 in order to structurally separate a subsequent main membrane portion 2b from an adjacent membrane edge portion 2d and to concentrate a capacitance measuring range on the main membrane portion 2b.

Following the formation of the etch access channels 9, a sacrificial layer etching is carried out, in which the first sacrificial layer O1, the second sacrificial layer O2 and the third sacrificial layer O3 are removed, so that a cavity 4 is formed in the device 1. The sacrificial layer etch can be carried out, for example, using a hydrogen-fluoride-based etching process.

According to the illustration in FIGS. 2G and 3F, a negative pressure can then be created in the cavity 4 and the cavity 4 can be sealed so as to be fluid tight, for example by plasma deposition with deposition of a dielectric layer 11a.

Subsequently, a metallic layer 11b can be deposited and structured in order to ensure a particularly robust and tight closure 11 of the etch access channels 9 over a long period of time. In addition, the metallic layer 11b can be used as a contact layer. The dielectric layer 11a and the metallic layer 11b are removed in all regions above the second membrane layer M2 apart from the closures 11, at least in the region of a subsequent main membrane portion 2d of the first membrane 2.

As shown in FIGS. 2H and 3G, a substrate recess 14 can then be produced in order to form, for example, a front and/or rear volume of the device 1. This can be done, for example, by rear-side etching, wherein the rear-side etching can advantageously stop on the special layer S if this is designed as an etch stop layer. In this case, the special layer S can subsequently be removed after the rear-side etching in order to ensure optimum mobility of the second membrane 3 at least in the main membrane portion 3d thereof.

FIGS. 2H and 3G illustrate the device 1 produced by means of the method described above and therefore correspond to FIGS. 1B and 1C discussed in connection with the device 1.

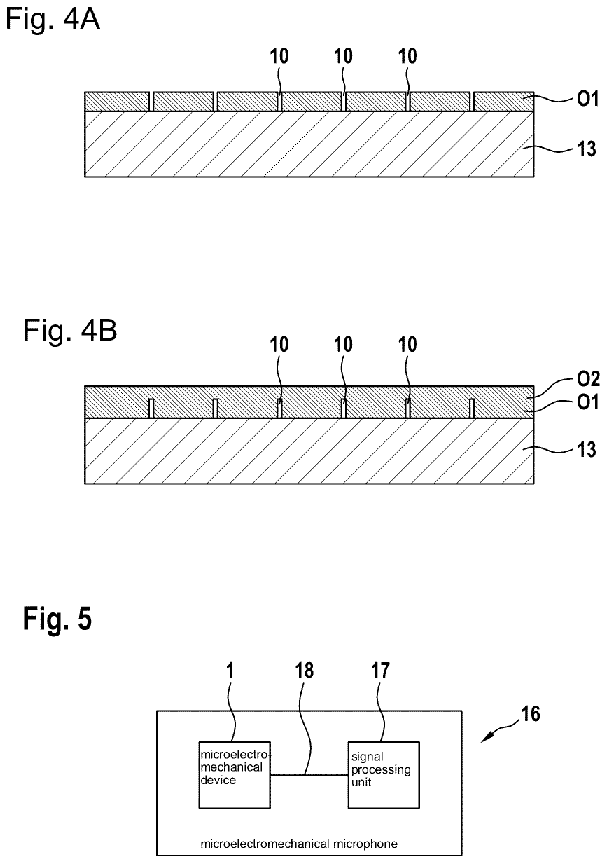

FIGS. 4A and 4B illustrate schematic diagrams to illustrate the generation of radial etch channels 10 in a first sacrificial layer O1 according to an exemplary embodiment. As shown in FIG. 4A, a first sacrificial layer O1 can first be deposited, for example, on a substrate 13 or in principle also on another material layer of a layer system applied to the substrate 13 and locally structured by etching in such a way that radial etch channels 10 which extend through the sacrificial layer O1 are formed. As shown in FIG. 4B, a further, second sacrificial layer O2 can then be deposited, for example, in order to close the etch channels 10 superficially and thereby form buried etch channels 10. By means of the radial etch channels 10, a homogeneous and rapid etching process can be made possible.

FIG. 5 schematically shows a microelectromechanical microphone 16 for capacitive sound pressure measurement and having a device 1 according to the above-described features and a signal processing unit 17 which is connected to the device 1 by a signal connection 18 and is designed to apply and process signals of the microelectromechanical device 1. The microelectromechanical microphone 16 can, for example, be implemented as a system-on-chip.

What is claimed is:

1. A microelectromechanical device for capacitive fluid pressure measurement, the device comprising:
a first membrane and a second membrane which can be elastically deflected by a fluid pressure, wherein a cavity is formed between the first membrane and the second membrane, a counter electrode being arranged in the cavity;
wherein the counter electrode includes a plurality of radial etch channels which extend radially from a counter electrode center to a counter electrode edge.

2. The device according to claim 1, wherein the counter electrode is spaced apart from a lateral cavity boundary of the cavity by a clearance channel which is circumferential at least in portions, and wherein the counter electrode has at least one support arm with which the counter electrode is anchored to the lateral cavity boundary and to which the counter electrode can be electrically contacted.

3. The device according to claim 2, wherein the clearance channel is fluidically connected to at least one etch access channel of the device, the etch access channel extending through the first membrane.

4. The device according to claim 3, wherein the etch access channel extends through a membrane edge portion of the first membrane, wherein the membrane edge portion extends radially from a membrane edge in a direction of a membrane center of the first membrane over a distance of at most 20% of the membrane diameter.

5. The device according to claim 1, wherein the counter electrode is arranged at least in portions between a main membrane portion of the first membrane and a main membrane portion of the second membrane opposite the main membrane portion of the first membrane.

6. The device according to claim 1, wherein the clearance channel is divided into several clearance channel segments and each clearance channel segment is fluidically connected to at least one etch access channel.

7. The device according to claim 6, wherein a gas volume that has a gas pressure below ambient air pressure is enclosed in the cavity.

8. The device according to claim 7, wherein the gas volume can be enclosed by a closure of the at least one etch access channel.

9. The device according to claim 8, wherein the closure includes a dielectric layer and/or a metallic layer.

10. The device according to claim 1, wherein the first membrane and/or the second membrane and/or the counter electrode is made of polysilicon.

11. A microelectromechanical microphone for capacitive sound pressure measurement, comprising:
a microelectromechanical device including:
a first membrane and a second membrane which can be elastically deflected by a fluid pressure, wherein a cavity is formed between the first membrane and the second membrane, a counter electrode being arranged in the cavity,
wherein the counter electrode includes a plurality of radial etch channels which extend radially from a counter electrode center to a counter electrode edge; and
a signal processing unit configured to apply and process signals from the microelectromechanical device.

12. A method for producing a microelectromechanical device for capacitive fluid pressure measurement having a first membrane and a second membrane which can be elastically deflected by a fluid pressure, wherein a cavity is formed between the first membrane and the second membrane, a counter electrode being arranged in the cavity, wherein method comprising:
gradually applying and structuring material layers on a substrate;
forming the cavity is formed by applying and subsequently etching at least one sacrificial layer;
wherein during manufacture, a counter electrode layer is applied to form a counter electrode, and the counter electrode layer and/or the sacrificial layer is structured in such a way that a plurality of radial etch channels is formed in the counter electrode and/or in the sacrificial layer, wherein the radial etch channels in the counter electrode extend: (i) radially from a counter electrode center to a counter electrode edge, and/or (ii) in the sacrificial layer.

13. The method according to claim 12, wherein the structuring of the counter electrode layer is carried out in such a way that the counter electrode is spaced apart from a lateral cavity boundary of the cavity by a clearance channel which is circumferential at least in portions and is anchored to the lateral cavity boundary with at least one support arm.

14. The method according to claim 12, wherein a first membrane layer is applied to produce the second membrane and a second membrane layer is applied to produce the first membrane and is structured such that at least one etch access channel is produced in a membrane edge portion of the first membrane.
